(19) United States
(12) Patent Application Publication
(10) Pub. No.: US 2009/0201075 A1
(43) Pub. Date: Aug. 13, 2009

(54) Method and Apparatus for MOSFET Drain-Source Leakage Reduction

(76) Inventor: Yannis Tsividis, New York, NY (US)

Correspondence Address: GLENN PATENT GROUP, 3475 EDISON WAY, SUITE L, MENLO PARK, CA, 94025, US

(21) Appl. No.: 12/399,759

(22) Filed: Mar. 6, 2009

Related U.S. Application Data
(63) Continuation-in-part of application No. 12/370,248, filed on Feb. 12, 2009.
(60) Provisional application No. 61/064,036, filed on Feb. 12, 2008.

(51) Int. Cl. H03K 3/01

(52) U.S. Cl. 327/534

(57) ABSTRACT

A method and apparatus are taught for reducing drain-source leakage in MOS circuits. In an exemplary CMOS logic gate, a first transistor causes the body of an affected transistor to be at a first body potential. A second transistor brings the body potential of the affected transistor to a second body potential by providing an accurate body voltage from a body voltage source. The first transistor's gate is controlled by a digital voltage source having a same polarity as that of an output of the CMOS logic gate and the second transistor is controlled by a digital voltage source having a same polarity as that of an input to the CMOS logic gate.

### CROSS REFERENCE TO RELATED APPLICATIONS

This patent application is a continuation-in-part of U.S. patent application Ser. No. 12/370,248, filed on 12 Feb. 2009, which claims priority from U.S. provisional patent application 61/064,036, filed on 12 Feb. 2008, both of which are incorporated herein in their entirety by this reference thereto.

### BACKGROUND OF THE INVENTION

1. Technical Field

The invention relates generally to MOS circuits. More specifically, the invention relates to improving drain-source leakage in deep submicron MOS transistors.

2. Discussion of Related Art

The advantages of using dynamically adjustable threshold voltages in metal oxide semiconductor (MOS) transistors, with regard to enhancing drive-current or reducing leakage current, is known. Two general types of approaches are presently known in the art. One approach attempts to create a dynamic threshold voltage by using simple active or passive elements, such as diodes, resistors, and/or capacitors to cause such change of the threshold voltage. Another class of prior art solutions uses additional MOS transistors to control the threshold voltage in a manner that reduces leakage current.

U.S. Pat. Nos. 7,224,205, 6,521,948, and 5,821,769, teach inventions that make use of a diode for the purpose of controlling leakage in MOS transistors. These solutions, as well as others known in the art, are not fully compliant in one way or another with standard CMOS process flows. This is because a general MOS process flow does not allow the creation of diodes in the general active area, although diodes some are allowed at the pad region of an integrated circuit (IC). The design rules do not allow diodes because this is thought to prevent errors in the design that may cause the faulty operation of the IC, or even permanent damage to the IC. To enable such solutions as may control leakage, the design rules must be relaxed and, in some prior art solutions, changes to the process flow are also required.

U.S. Pat. Nos. 6,952,113, 6,744,301, 6,441,647, 6,304,110, 6,291,857, 6,118,328, 5,994,177, and 5,644,266 teach examples of solutions that use additional circuitry comprising MOS transistors to achieve reduced leakage of the MOS circuit. The MOS transistors that are controlled by these circuits connect the fourth terminal of the MOS transistor, i.e. the body, the other three terminals being the gate, source and drain, to an appropriate voltage to control the threshold voltage in a desired manner. Various solutions use a different number of transistors to control the leakage of the transistors and generally have a larger impact on a cell size than the first approach discussed above. These solutions have the advantage of not deviating from the standard process. They suffer, however, from various shortcomings, including an unpredictable body potential due to leakage currents and other factors, and a requirement for a direct current (DC) input draw.

There is a therefore a need in the art for a circuit which can reduce the drain-source leakage of MOS transistors and further overcome the deficiencies of prior art solutions.

### SUMMARY OF THE INVENTION

A method and apparatus are taught for reducing drain-source leakage in MOS circuits. In an exemplary CMOS logic gate, a first transistor causes the body of an affected transistor to be at a first body potential. A second transistor brings the body potential of the affected transistor to a second body potential by providing an accurate body voltage from a body voltage source. The first transistor's gate is controlled by a digital voltage source having a same polarity as that of an output of the CMOS logic gate and the second transistor is controlled by a digital voltage source having a same polarity as that of an input to the CMOS logic gate.

### BRIEF DESCRIPTION OF THE DRAWINGS

FIG. 1 is a schematic diagram of a circuit having leakage control in accordance with the invention;

FIG. 2 is a schematic diagram of a first exemplary body voltage generator circuit for current leakage control in accordance with the invention;

FIG. 3 is a schematic diagram of a second exemplary body voltage generator circuit for current leakage control in accordance with the invention; and

FIG. 4 is a schematic diagram of a circuit having leakage control performed from independent sources in accordance with the invention.

### DETAILED DESCRIPTION OF THE INVENTION

An embodiment of the invention provides a method and apparatus for reducing leakage in MOS circuits. In an exemplary CMOS inverter, a first transistor causes the body of a controlled transistor to be at a first body potential. A second transistor brings the body potential of the controlled transistor to a second body potential by providing an accurate body voltage from a body voltage source. Exemplary body voltage sources that can drive one or more gate transistors of different gate circuits are also described herein. Although CMOS circuits are emphasized as an example, the invention described herein is also applicable in technologies where only one transistor type is available, e.g. NMOS or PMOS.

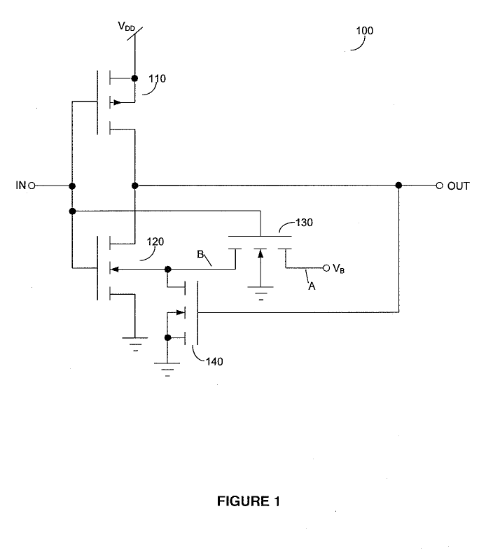

FIG. 1 is a schematic diagram that shows a circuit 100 the implements leakage control in accordance with an embodiment of the invention. While the invention is described herein in the context of a complementary metal oxide semiconductor (CMOS) inverter, also referred to in the art as a NOT gate, comprising a P-type MOS (PMOS) transistor 110 and an N-type MOS (NMOS) transistor 120, it will be apparent to those skilled in the art that the invention may be extended to other types of CMOS gates including, but not limited to, NAND, NOR, AND, OR, XOR, NXOR, AND-OR, and OR-AND gates.

A control circuit comprising a first NMOS transistor 130 and a second NMOS transistor 140 enhance the operation of a controlled NMOS transistor 120. Similarly, PMOS transistors (not shown) enhance the operation of PMOS transistor 110 in accordance with the invention. The first NMOS transistor 130 operates advantageously in the triode region when ON, thereby connecting the body of the controlled NMOS transistor 120 to a predetermined, typically positive voltage V_{B}, which is supplied by a separate circuit (not shown). The production of a voltage V_{B} is explained in greater detail below. When the input at the terminal IN is high, the threshold voltage V_{T} of the controlled NMOS transistor 120 is lowered, resulting in the enhancement of its ON current relative to what the current would have been if the body were at ‘0’ potential. This is because, as is well known, the threshold voltage of NMOS transistors decreases when their body is made positive with respect to their source. Because the input terminal IN is high, the output terminal OUT is low, thus keeping the second NMOS transistor 140 in an OFF state. When the input at the IN terminal is low, the first NMOS transistor 130 is in an OFF state. In this case, the output terminal OUT goes high and causes the second NMOS transistor 140 to enter the ON state. This pulls the body of the controlled NMOS transistor 120 to low, resulting in its threshold voltage V_{T} assuming its normal, zero-body-source voltage value, which is higher than its previous value. This value can be chosen through process engineering for low drain-source leakage current, and does not adversely affect the ON current due to the V_{T} reduction in the ON state.

The ratio of the drain current in controlled NMOS transistor 120 with body bias to the value of that current without body bias is defined herein as the current enhancement ratio (CER). THE CER is denoted by the character a and is further discussed below with respect to the generation of the body voltage. First and second NMOS transistors 130 and 140, respectively, only need to conduct extremely small currents, so they can be minimum size if the parasitic capacitance they drive is not large. Thus, if the controlled NMOS transistor 120 is not a minimum-size transistor, the additional area needed to include the first and second NMOS transistors 130 and 140 is relatively small. Specifically, the disclosed invention is of particular benefit for large drivers, which consume much area and have a high total leakage current. The loop consisting of the controlled NMOS transistor 120 and the first NMOS transistor 130 provides a regenerative action. The circuit is preferably designed so that the positive feedback in that loop does not result in undesirable instability. In one embodiment of the invention, this action enhances the speed of the circuit 100 to some extent. To avoid positive feedback, the second NMOS transistor 140 could be replaced by another conductive path to ground. However, this may cause a DC current to flow through the first NMOS transistor 130 in the ON condition, thus defeating the purpose unless this current is extremely small.

A person skilled in the art would readily appreciate that the disclosed circuit 100 uses only standard transistors, which are well characterized. No new design rules are needed, and no technology modifications are required, other than the threshold voltage V_{T} adjustment, which is well known in the art. It will be further appreciated that the body of the controlled transistor 120 is not floating when the input terminal IN is low or high. Rather, it is reliably pulled to ground potential via the second NMOS transistor 140, or to the voltage V_{B} via the first NMOS transistor 130. Thus, the body potential does not depend on unpredictable leakage currents. Furthermore, it will be appreciated that no DC input current drawn by application of the invention herein. A person skilled in the art would further realize that the body voltage can be made to have a reliable and appropriate value. Two exemplary and non-limiting body voltage circuits are described below.

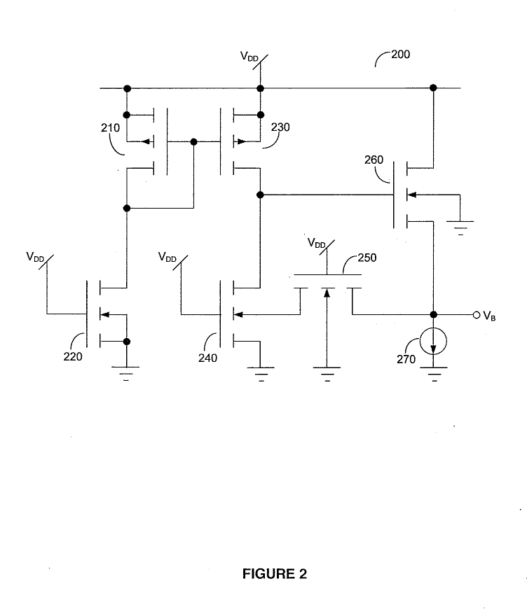

FIG. 2 is a schematic diagram that shows a body voltage generator circuit 200 according to the invention. In the body voltage generator circuit 200, the body voltage of the transistor 240, i.e. the adaptive body bias device, is set to make its drain current I_{D240} equal to a times the current the device would have if its body voltage were 0. It should be recalled that a is the CER defined above. All transistors, except for the transistor 250, are in saturation, and all currents and voltages and currents mentioned below are those that exist when these devices are steady, i.e. as opposed to when transients charging parasitic capacitances exist. For simplicity, the Early effect is neglected for purposes of the description of the body voltage generator circuit 200. The transistors 210 and 230 form a 1:1 current mirror. The transistor 220, which is the reference current device, and the transistor 240 have an equal channel length ‘L’, but the channel width ‘W’ of the transistor 220 is a>1 times the width of the transistor 240. For analysis purposes, it is assumed that the body of transistor 240 is initially at ‘0’. In this case it is determined that:

I_{D220}=a×I_{D240}>I_{D240} (1)

Because,

I_{D230}=I_{D210}=I_{D220} (2)

Then,

I_{D230}>I_{D240} (3)

resulting in an increase of the drain voltage V_{D240} of the transistor 240. This increase is coupled by the source follower transistor 260, which is biased by the current source 270, to the body of the transistor 240 through the ON switch transistor 250. The increase in the body voltage V_{B240} of the transistor 240 increases I_{D240}, until:

I_{D240}=I_{D230}=I_{D210}=I_{D220} (4)

As a result, the body voltage V_{B} attains a voltage value that is needed to make the drain current I_{D240} with body bias equal to the drain current I_{D220} without body bias, which is a times the current value I_{D240} without body bias. Thus:

I_{D240} with body bias=a×ID₂₄₀ without body bias (5)

The CER is set to the desired value a. The resulting voltage V_{B} may be fed to one or more NMOS transistors elsewhere on the chip connected, for example, at the terminal marked V_{B} in FIG. 1. The transistor 250 replicates the function of the first NMOS transistor 130 in FIG. 1 to assure good matching. The transistor 250 carries only a minute portion of the body current of the transistor 240. Because the transistor 240 is in the triode region, it has a rather small channel resistance and the voltage across it may be negligible. In that case, this device may be omitted. The feedback loop described above can be made more sensitive by inserting a voltage gain in the loop, for example at the input or the output of the source follower transistor 260.

The W/L ratios shown herein above are exemplary and are provided merely as an illustration of the principles of the invention. It will be apparent to those of ordinary skill in the art that ratios other than the above can be used. For example, the current mirror consisting of the transistors 210 and 230 can have a current ratio different than 1 if the sizes of the transistors 220 and 240 are appropriately altered to maintain the desired CER. The W/L ratios of the transistors should satisfy:

[(W/L)₂₂₀/(W/L)₂₄₀]×[(W/L)₂₃₀/(W/L)₂₁₀]=a (6)

The current sources can be implemented using transistors and the application of well-known design techniques.

The CER value a can be made programmable or tunable. For example, one or more of the four transistors 220, 210, 230, and 240 can be comprised of a plurality of transistors connected in parallel, some of which may be placed out of service as required by connecting their gates to their sources. This can be done, for example, by selecting the appropriate connections through electronic switches (not shown) an/or by digital control (not shown). Thus, the CER can be varied or tuned as required, for example but without limitation, responsive to process tolerances, temperature, and/or aging. Such CER variation can also be effected by injecting an appropriate current at the common drain node between the transistors 220 and 210 or the transistors 230 and 240, this current being an appropriate function of process tolerances, temperature, and aging, as required.

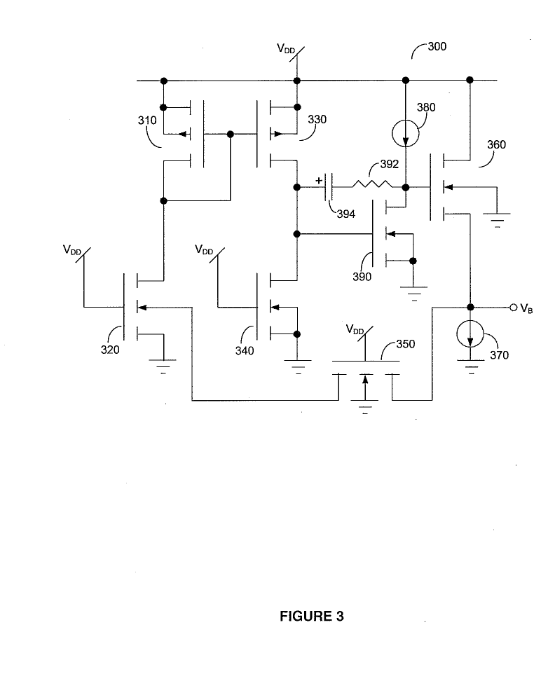

FIG. 3 is a schematic diagram that shows another embodiment of a body voltage generator circuit 300 according to the invention. The body voltage generator circuit 300 provides a large loop gain by modifying certain elements of the body voltage generator circuit 200, shown in FIG. 2. For the purpose of the following analysis, it is assumed that the channel lengths of the transistor 320, which is the adaptive body bias device, and the transistor 340, which is the current reference device, are equal, and that the width of the transistor 340 is a times the width of the transistor 320, where a>1. For example, it can be assumed that the current mirror formed by the transistors 310 and 330 is 1:1. For analysis purposes, it is also assumed that the body voltage V_{B} is initially ‘0’. Therefore:

ID₃₃₀<I_{D340} (7)

and the drain voltage V_{D340} of the transistor 340 decreases. Thus, the output of the inverter comprising the transistor 390 and the current source 380 increases. This increase is coupled through the source follower transistor 360, the current source 370, and ON switch transistor 350 to the body of the transistor 320, thus increasing its current. Equilibrium is achieved when:

I_{D320}=I_{D310}=I_{D330}=I_{D340} (8)

which means, following the same reasoning provided with respect of the body voltage generator circuit 200 shown in FIG. 2, that:

I_{D320} with body bias=a×I_{D320} without body bias (9)

Hence, in the body voltage generator circuit 300 the CER is set to the desired value a. The extra inverter in the loop, i.e. the transistor 390 and current source 380, provides extra loop gain. A resistor 392 and a capacitor 394 are used to compensate the loop using standard feedback compensation practice to ensure stability. The W/L ratios in the above example are provided for illustration purposes only and are not meant to limit the scope of the invention. It will be apparent to those skilled in the art that ratios other than those set forth above can be used. For example, the current mirror consisting of the transistors 310 and 330 can have a current ratio different from 1, if the sizes of the transistors 320 and 340 are appropriately altered to maintain the desired CER. The W/L ratios of the transistors should satisfy:

[(W/L)₃₄₀/(W/L)₃₂₀]×[(W/L)₃₁₀/(W/L)₃₃₀]=a (10)

The current sources above can be implemented with transistors using standard design techniques.

The CER value a can be programmable or tunable. For example, one or more of the four transistors 320, 310, 330, and 340 can be comprised of a plurality of transistors connected in parallel, some of which may be placed out of service as may be required by connecting their gates to their sources. This can be done, for example, by selecting the appropriate connections through electronic switches (not shown) and/or a digital control (not shown). Thus, the CER can be varied or tuned as required, for example, responsive to process tolerances, temperature, and/or aging. Such CER variation can also be effected by injecting an appropriate current at the common drain node between the transistors 320 and 310 or the transistors 330 and 340, this current being an appropriate function of process tolerances, temperature, and aging, as required.

The output voltage V_{B} of either of the body voltage generator circuits 200 and 300 feeds the body of one or more other NMOS transistors on the chip. Specifically, thousands of such transistors may be connected to such body voltage circuits to achieve the benefits of the invention. Therefore, the invention overcomes the problem of other approaches in prior art that either require a dedicated body voltage supply for each transistor, or that compromise by not providing the desired and necessary body voltage, as explained above. In fact, with regard to the invention a single body voltage V_{B} generator can feed substantially all of the NMOS transistors throughout the chip if the degree of matching achieved is satisfactory. If matching is not satisfactory, the transistors in a given neighborhood can be fed by a body voltage V_{B} generator that is provided specifically for these transistors, for example, by placing the voltage generator circuit in proximity to such transistors to ensure transistor matching. Different neighborhoods, then, have different body voltage V_{B} generators.

The body bias generator circuits shown in FIGS. 2 and 3 can be used independently of the circuit shown in FIG. 1 to feed the body bias of other appropriate circuits.

A method is also disclosed herein for forming a circuit to control leakage of a MOS transistor. Accordingly, a MOS transistor is formed, the MOS transistor having a gate terminal, a drain terminal, a source terminal, and a body terminal. In accordance with the invention, a control circuit is coupled to the body terminal of the MOS transistor, such that the body receives a first reference potential in one instance and a second reference potential in another. By controlling the kind of potential provided to the transistor, it is possible to ensure that the leakage characteristics of the transistor are controlled. The control circuit is formed as explained in more detail herein above.

In one embodiment of the invention, the body voltage VB is tied to the supply voltage VDD. In such case, a level shifter adjusts the voltage levels to the desired voltage level in accordance with the principles discussed hereinabove. Such a level shifter may be connected between the supply voltage VDD and the drain terminal of the transistor 130 at location A in FIG. 1. In another embodiment, the level shifter is connected between the source of the transistor 130 and the drain of the transistor 140 at location B in FIG. 1. In yet another embodiment of the invention, a capacitor (not shown) may be connected between the gate and source of the transistor 130 for improved performance at transient times when the transistor 120 switches from ON to OFF or vice versa.

In an embodiment of the invention, an equivalent transistor 140 is used to bring the body voltage of a controlled transistor to a first body voltage for the OFF state of the controlled transistor, for example the transistor 120. A second transistor, such as the transistor 130, brings the body of the gate transistor, for example the transistor 120, to a second body voltage at the ON state, thereby effectively causing the controlled transistor, for example the transistor 120, to have two separate threshold voltages. The second body voltage is provided from an accurate body voltage source, as described in more detail above.

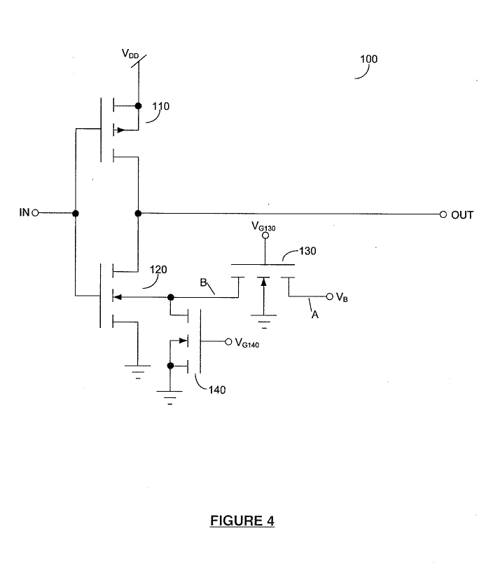

In an embodiment of the invention shown in FIG. 4, rather than connecting the gate of the transistor 140 to the OUTPUT, the gate is provided with a potential V_{G140} from an independent source. Such an independent source typically provides a signal that corresponds to an inverted version of the IN signals of the transistors 110 and 120. For example, an inverter, typically of minimum size, is connected from the IN signal to generate V_{G140}. Similarly, a signal corresponding to the IN signal, but derived by independent means, or otherwise corresponding to the inverted version of the OUT signal, may be provided as V_{G130} of the transistor 130. One or both control signals may be provided from a preceding circuit, if such a preceding circuit has versions of the IN signal and/or its inversion, and the OUT signal and/or its inversion. In the more general case, more complex gates, such as NAND or NOR gates, may also benefit from the invention.

While the invention disclosed herein is described with respect to NMOS transistors, this should not be viewed as limiting the scope of the invention. A person skilled in the art would readily acknowledge that the invention can be adapted to operate with respect to PMOS transistor, and that such adaptation is straightforward and does not involve any undue burden in its implementation. Furthermore, the invention is described with respect to an inverter. However, other circuits may be used including, but without limitation, circuits such as NOR and NAND gates. The invention disclosed herein may also be used to reduce other leakage currents.

Although the invention is described herein with reference to the preferred embodiment, one skilled in the art will readily appreciate that other applications may be substituted for those set forth herein without departing from the spirit and scope of the present invention. Accordingly, the invention should only be limited by the Claims included below.

1. A leakage control circuit for a complementary metal-oxide semiconductor (CMOS) gate, comprising:
a CMOS logic gate comprising a first N-type metal-oxide semiconductor (NMOS) transistor and a first P-type metal-oxide semiconductor (PMOS) transistor, each transistor having a body terminal, a drain terminal, a source terminal, and a gate terminal; and
a control circuit coupled to at least one of said first NMOS transistor and said first PMOS transistor, said control circuit comprising:
a first transistor coupled to said body terminal of any of said NMOS transistor and said PMOS transistor to bring said body terminal to a first reference potential; and
a second transistor coupled to said body terminal of any of said NMOS transistor and said PMOS transistor to bring said body terminal to a second reference potential, said second reference potential provided by a body bias voltage supply that provides a bias voltage to establish a predetermined current enhancement ratio (CER);
wherein said first transistor's gate is controlled by a digital voltage source having a same polarity as that of an output of said CMOS logic gate and said second transistor is controlled by a digital voltage source having a same polarity as that of an input to said CMOS logic gate.

2. The circuit of claim 1, wherein said CER expresses a ratio between a current of said drain of any of said NMOS transistor and said PMOS transistor with body bias to a current of said drain of any of said NMOS transistor and said PMOS transistor without body bias.

3. The circuit of claim 1, wherein said CER expresses a ratio of width over the length of a reference current device and width over length of an adaptive body bias device, multiplied by a ratio of width over length of a first transistor of a current mirror circuit of said body bias voltage supply and a second transistor of a current mirror circuit of said body bias voltage supply.

4. The circuit of claim 1, wherein the CMOS gate comprises any of an inverter, NAND, NOR, AND, OR, XOR, NXOR, AND-OR, and OR-AND.

5. The circuit of claim 1, further comprising:
a second CMOS logic gate, wherein the leakage control circuit controls the leakage of said second CMOS logic gate.

6. The circuit of claim 1, further comprising:
a voltage shifter coupled between a drain terminal of said second transistor and said body bias voltage supply.

7. The circuit of claim 1, further comprising:
a voltage shifter coupled between a source terminal of said second transistor and a drain terminal of said first transistor.

8. The circuit of claim 1, further comprising:
a capacitor coupled between a gate terminal of said second transistor and a source terminal of said second transistor.

9. A circuit comprising:
a first MOS transistor having a gate terminal, a source terminal, a drain terminal, and a body terminal; and
a control circuit coupled to said MOS transistor, said control circuit comprising:
a second MOS transistor coupled to said body terminal of said first MOS transistor to bring said body terminal to a first reference potential; and
a third MOS transistor coupled to said body terminal to bring said body terminal of said first MOS transistor to a second reference potential, said second reference potential provided by a body bias voltage supply to establish a predetermined current enhancement ratio (CER);
said control circuit controlling leakage of said first MOS transistor;
wherein said second transistor's gate is controlled by a digital voltage source having a same polarity as that of an output of said CMOS logic gate, and said third transistor controlled by a digital voltage source having a same polarity as that of an input to said CMOS logic gate.

10. The circuit of claim 9, wherein said CER expresses ratio between a current of said drain of said first MOS transistor with body bias to a current of said drain of said first MOS transistor without body bias.

11. The circuit of claim 9, wherein said first MOS transistor is any of a P-type MOS (PMOS) transistor and an N-type MOS (NMOS) transistor.

12. The circuit of claim 9, wherein said CER expresses a ratio of width over length of a reference current transistor and width over length of an adaptive body bias transistor, multiplied by a ratio of width over length of a first transistor of a current mirror circuit of said body bias voltage supply and a second transistor of said current mirror circuit of said body bias voltage supply.

13. The circuit of claim 9, wherein said MOS device comprises a portion of a logic gate.

14. The circuit of claim 13, wherein said logic gate comprises any of an inverter, NAND, NOR, AND, OR, XOR, NXOR, AND-OR, and OR-AND.

15. The circuit of claim 9, wherein said control circuit is connected to at least one other MOS transistor of the same type of said MOS transistor.

16. The circuit of claim 9, further comprising:
a voltage shifter coupled between a drain terminal of said third transistor and said body bias voltage supply.

17. The circuit of claim 9, further comprising:
a voltage shifter coupled between a source terminal of said third transistor and a drain terminal of said second transistor.

18. The circuit of claim 9, further comprising:
a capacitor coupled between a gate terminal of said third transistor and a source terminal of said third transistor.

19. A body voltage control circuit for controlling leakage of a metal-oxide semiconductor (MOS) transistor, comprising:
a first transistor coupled to a body terminal of the MOS transistor to bring said body terminal of the MOS transistor to a first reference potential;
a second transistor coupled to said body terminal of the MOS transistor to bring said body terminal of the MOS transistor to a second reference potential; and
a body bias voltage supply coupled to said second transistor to establish a predetermined current enhancement ratio (CER);
wherein said first transistor's gate is controlled by a digital voltage source having a same polarity as that of an output of said CMOS logic gate and said second transistor controlled by a digital voltage source having a same polarity as that of an input to said CMOS logic gate.

20. The circuit of claim 19, wherein said CER expresses a ratio between a current of said drain of the MOS transistor with body bias to a current of said drain of the MOS transistor without body bias.

21. The circuit of claim 19, wherein the MOS transistor comprises any of a P-type MOS (PMOS) transistor and an N-type MOS (NMOS) transistor.

22. The claim 19, wherein said CER expresses a ratio of width over length of a reference current device and width over length of an adaptive body bias device, multiplied by a ratio of width over length of a first transistor of a current mirror circuit of said body bias voltage supply and a second transistor of a current mirror circuit of said body bias voltage supply.

23. The circuit of claim 19, further coupled to at least a second MOS transistor to control leakage of said second MOS transistor.

24. The circuit of claim 19, further comprising:
a voltage shifter coupled between a drain terminal of said second transistor and said body bias voltage supply.

25. The circuit of claim 19, further comprising:
a voltage shifter coupled between a source terminal of said second transistor and a drain terminal of said first transistor.

26. The circuit of claim 19, further comprising:
a capacitor coupled between a gate terminal of said second transistor and a source terminal of said second transistor.

27. A method of manufacturing a leakage control circuit to control leakage of a metal-oxide semiconductor (MOS) transistor comprising the steps of:
forming the MOS transistor on a substrate, the MOS transistor having a gate terminal, a drain terminal, a source terminal, and a body terminal;
forming a first MOS transistor coupled to said body terminal of the MOS transistor to bring said body terminal of the MOS transistor to a first reference potential;
forming a second MOS transistor coupled to said body terminal of the MOS transistor to bring said body terminal of the MOS transistor to a second reference potential;
providing a first digital control voltage to said first MOS transistor, said first digital control voltage having an opposite polarity of that of the input signal to said MOS transistor; and
providing a second digital control voltage to said first MOS transistor that has a same polarity as that of the input signal of said MOS transistor;
said second reference potential provided by a body bias voltage supply comprising a bias voltage that establishes a predetermined current enhancement ratio (CER).

28. The method of claim 27, further comprising the step of:
expressing said current enhancement ratio (CER) as the ratio between a current of said drain of the MOS transistor with body bias to a current of said drain of the MOS transistor without body bias.

29. The method of claim 27, further comprising the step of:
expressing said CER as a ratio of width over length of a reference current device and width over length of an adaptive body bias device, multiplied by a ratio of width over length of a first transistor of a current mirror circuit of said body bias voltage supply and a second transistor of a current mirror circuit of said body bias voltage supply.

30. The method of claim 27, said MOS device comprising any of a P-type MOS (PMOS) transistor and an N-type MOS (NMOS) transistor.

31. The method of claim 27, further comprising the step of:
forming a connection between the leakage control circuit of claim 27 and a second MOS transistor to control leakage of said second MOS transistor.

32. The method of claim 27, further comprising the step of:
forming a voltage shifter coupled between a drain terminal of said second transistor and said body bias voltage supply.

33. The method of claim 27, further comprising the step of:
forming a voltage shifter coupled between a source terminal of said second transistor and a drain terminal of said first transistor.

34. The method of claim 27, further comprising the step of:
forming a capacitor coupled between a gate terminal of said second transistor and a source terminal of said second transistor.
